(19) United States
(12) Patent Application Publication
(10) Pub. No.: US 2011/0132457 A1
(43) Pub. Date: Jun. 9, 2011

(54) CONCENTRATING SOLAR COLLECTOR WITH SHIELDING MIRRORS

(75) Inventor: Marc A. Finot, Palo Alto, CA (US)

(73) Assignee: Skyline Solar, Inc., Mountain View, CA (US)

(21) Appl. No.: 12/960,219

(22) Filed: Dec. 3, 2010

Related U.S. Application Data
(60) Provisional application No. 61/266,823, filed on Dec. 4, 2009.
(60) Provisional application No. 61/362,591, filed on Jul. 8, 2010.

(51) Int. Cl. H01L 31/0232

(52) U.S. Cl. 136/259

(57) ABSTRACT

One aspect of the invention relates to an arrangement for use in a concentrating solar collector that involves a solar receiver that is covered by a shielding mirror. The shielding mirror is attached with and positioned over the solar receiver to help deflect incident light away from the underlying solar receiver. In various embodiments, the shielding mirror is arranged to direct the light to a photovoltaic cell on another solar receiver. Another aspect of the invention pertains to a concentrating solar collector that utilizes the above arrangement.

### CROSS-REFERENCE TO RELATED APPLICATIONS

This application claims priority to U.S. Provisional Patent Application No. 61/266,823, entitled “Concentrating Solar Collector with Supplementary Mirrors,” filed Dec. 4, 2009, and U.S. Provisional Patent Application No. 61/362,591, entitled “Optimized Solar Collector,” filed Jul. 8, 2010, which are hereby incorporated by reference in their entirety for all purposes.

### FIELD OF THE INVENTION

The present invention relates to solar technologies. More specifically, the present invention relates to various collector, reflector and mirror designs for concentrating photovoltaic systems.

### BACKGROUND OF THE INVENTION

Typically, the most expensive component of a photovoltaic (PV) solar collection system is the photovoltaic cell. To help conserve photovoltaic material, concentrating photovoltaic (CPV) systems use mirrors or lenses to concentrate solar radiation on a smaller cell area. Since the material used to make the optical concentrator is less expensive than the material used to make the cells, CPV systems are thought to be more cost-effective than conventional PV systems.

One of the design challenges for any CPV system is the need to balance multiple priorities. For one, a CPV system requires a support structure that arranges the optical concentrators and the photovoltaic cells such that incoming sunlight is efficiently converted into electricity. This support structure should also accommodate a tracking system and provide for the adequate dissipation of heat. Another consideration is the cost of manufacturing, installing and repairing the CPV system. Existing CPV designs address these issues in a wide variety of ways. Although existing CPV systems work well, there are continuing efforts to improve the performance, efficiency and reliability of CPV systems.

### SUMMARY OF THE INVENTION

One aspect of the present invention relates to a solar receiver that is suitable for use in a solar collector and that is covered by a shielding mirror. In various embodiments, the shielding mirror helps direct incident sunlight towards a photovoltaic cell on another solar receiver. Alternatively, the shielding mirror may help direct incident sunlight towards a photovoltaic cell on the solar receiver beneath the shielding mirror. Thus, incoming solar radiation that would otherwise be wasted on non-cell portions of the solar receiver is instead converted into electricity by the solar collector.

The shielding mirrors may be flat, curved and/or have a parabolic shape. The shielding mirror may be supported over the solar receiver such that a gap is formed between the shielding mirror and the solar receiver. The gap is arranged to allow convective air flow to help dissipate heat from the solar receiver. In some embodiments, multiple shielding mirrors are made from a single reflective material and are arranged to overlie two adjacent solar receivers. In still other embodiments, the shielding mirror is segmented. That is, the shielding mirror is made of multiple individual mirrors that are separated by gaps. These gaps allow natural convective air flow and help cool the underlying solar receiver.

In another aspect of the present invention, a concentrating solar collector includes multiple reflectors that extend along a longitudinal axis. Multiple solar receivers are positioned at various locations in the solar collector. The reflectors are arranged to direct incident sunlight to photovoltaic cells on the solar receivers. A shielding mirror is positioned over each solar receiver. The shielding mirror is arranged to reflect incident light away from the underlying solar receiver during the normal operation of the solar collector. The shielding mirror is also arranged to help direct the reflected light to a photovoltaic cell on one of the solar receivers.

### BRIEF DESCRIPTION OF THE DRAWINGS

The invention and the advantages thereof, may best be understood by reference to the following description taken in conjunction with the accompanying drawings in which:

FIG. 1 is a diagrammatic cross-sectional view of a longitudinally extended solar collector.

FIG. 2 is a diagrammatic cross-sectional view of a solar collector with shielding mirrors according to a particular embodiment of the present invention.

FIG. 3A is a diagrammatic side view of a solar receiver and a shielding mirror according to a particular embodiment of the present invention.

FIG. 3B is a diagrammatic perspective frontal view of a solar receiver and a shielding mirror according to a particular embodiment of the present invention.

FIG. 4A is a diagrammatic side view of two adjacent solar receivers and two shielding mirrors in accordance with a particular embodiment of the present invention.

FIG. 4B is a diagrammatic side view of a solar receiver with a shielding mirror made of a plurality of individual mirrors according to a particular embodiment of the present invention.

FIG. 5 is a diagrammatic side view of a solar receiver with a segmented shielding mirror and a secondary mirror according to a particular embodiment of the present invention.

FIG. 6 is a diagrammatic cross-sectional view of a solar collector with tilted solar receivers according to a particular embodiment of the present invention.

FIG. 7 is a diagrammatic cross-sectional view of a solar collector with extended shielding mirrors according to a particular embodiment of the present invention.

FIG. 8 is a diagrammatic cross-sectional view of a solar collector with shielding mirrors according to a particular embodiment of the present invention.

FIG. 9 is a diagrammatic cross-sectional view of a solar collector with shielding mirrors according to another embodiment of the present invention.

### DETAILED DESCRIPTION OF THE PREFERRED EMBODIMENTS

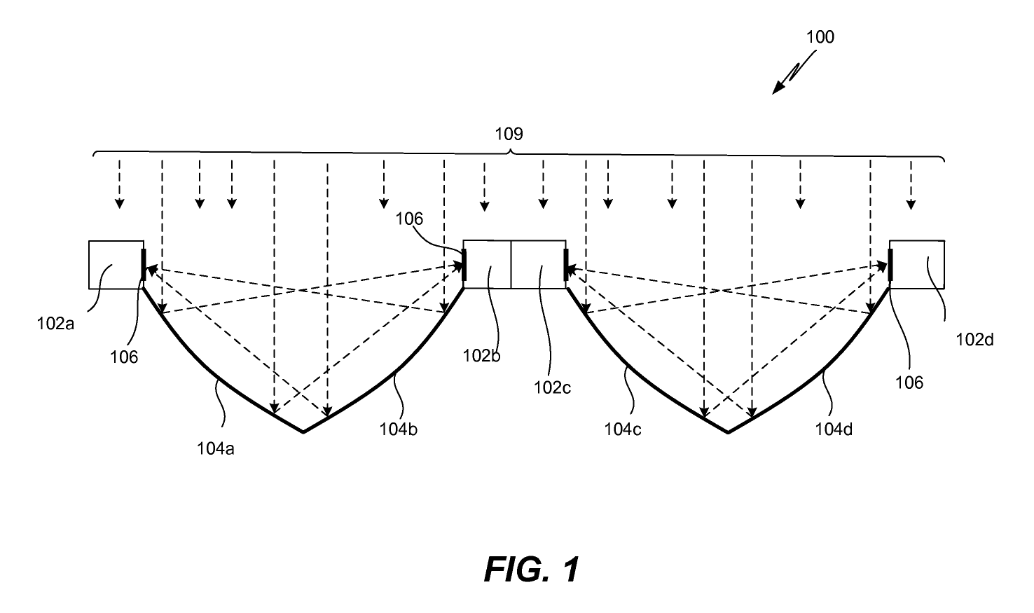

The present invention relates generally to reflector and mirror designs for concentrating photovoltaic (CPV) systems. The assignee for the present application, Skyline Solar, Inc., has received multiple patents related to such designs, such as U.S. Pat. No. 7,709,730, entitled “Dual Trough Concentrating Solar Photovoltaic Module,” filed Apr. 10, 2008, which is hereby incorporated by reference in its entirety for all purposes and is hereinafter referred to as the '730 patent. An embodiment of a collector design described in the '730 patent is shown in FIG. 1. FIG. 1 illustrates a solar collector 100 that includes multiple solar receivers 102a-102d and reflectors 104a-104d. The reflectors 104a-104d extend in a longitudinal direction. As shown by the arrows in the figure, the reflectors 104a-104d are arranged to direct incident sunlight 109 to photovoltaic cells 106 on the solar receivers 102a-102d.

While the design illustrated in FIG. 1 works well for many applications, there are ways in which it could be improved. In particular, some incident sunlight misses the photovoltaic cells 106 and instead strikes the non-cell portions of the solar receivers 102a-102d. This is undesirable for various reasons. For one, the sunlight that strikes the top surfaces and non-cell portions of the solar receivers is wasted rather than being converted into electricity. That is, the ratio of reflector area to the total area of the collector is reduced by the area of the solar receivers. Secondly, prolonged exposure to ultraviolet radiation can degrade the solar receiver. Additionally, some of the unconverted sunlight striking the non-cell portions of the solar receivers may be absorbed. This can heat the solar receiver, increase its temperature and reduce the efficiency of its photovoltaic cells.

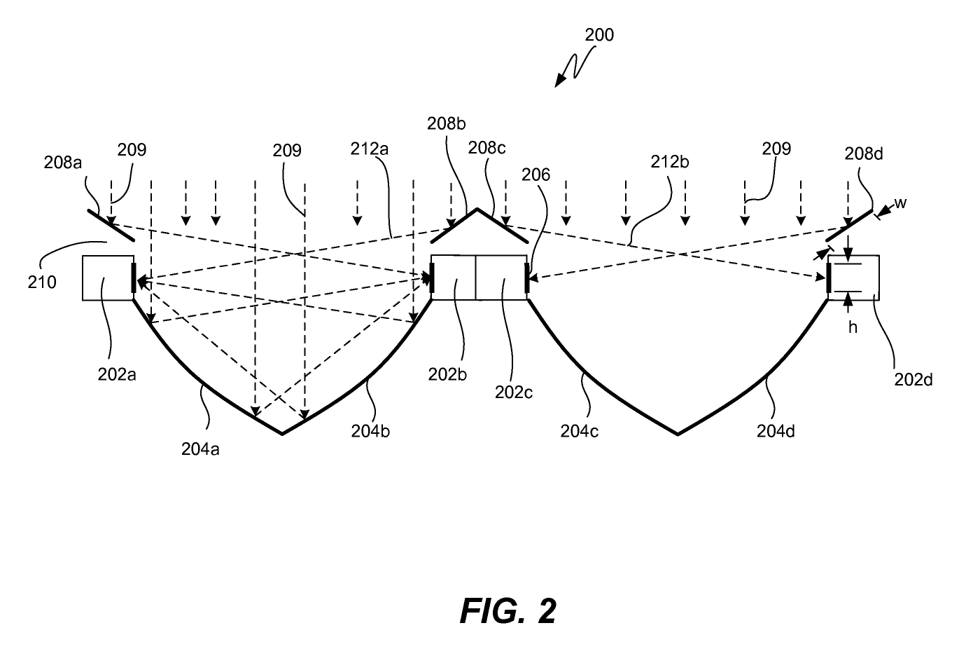

The present application describes various technologies that address one or more of the above concerns. Initially, with reference to FIG. 2, a solar collector 200 according to one embodiment of the present invention will be described. The solar collector 200 is similar in some respects to the one illustrated in FIG. 1. The solar collector 200 includes reflectors 204a-204d and solar receivers 202a-202d. A support structure physically supports the collector 200. A tracking system is arranged to cause the collector 200 to track movements of the sun along at least one axis. An additional feature is shielding mirrors 208a-208d, which are positioned over the solar receivers 202a-202d. The shielding mirrors are all longitudinally extended and may have approximately the same or similar length as the reflectors 204a-204d and receivers 202a-202d. Shielding mirrors 208a and 208c may be parallel to one another and shielding mirrors 208b and 208d may also be parallel to each other. A support structure (not shown) holds the shielding mirrors in place over the solar receivers and physically supports the various components of the collector. The shielding mirrors 208a-208d make productive use of incident sunlight 209 that would otherwise be lost on the top surfaces of the solar receivers 202a-202d.

Each shielding mirror 208a-208d reflects incident sunlight away from the underlying solar receiver and towards a photovoltaic cell 206 on another solar receiver. That is, the shielding mirror 208a-208d does not direct light towards the photovoltaic cell on the solar receiver that it overlies. Instead, it directs the sunlight to another solar receiver that is positioned some distance away from the underlying solar receiver and whose cell face may be facing at least partially towards the shielding mirror. In the illustrated embodiment, for example, the first shielding mirror 208a, which is positioned over the first solar receiver 202a and next to a top edge of the first reflector 204a, directs incident light 209 to a photovoltaic cell 206 on the second solar receiver 202b. The second shielding mirror 208b, which is positioned over the second solar receiver 202b and near a top edge of the second reflector 204b, directs light to a photovoltaic cell 206 on the first solar receiver 202a. Each shielding mirror redirects some or all of the incident light that would otherwise strike the underlying solar receiver.

The shielding mirror may be made of any suitably reflective material, such as aluminum or another metal. Products such as Miro-sun®, which is made by Alanod of Ennepatal, Germany, and ReflecTech®, which is made by ReflectTech, Inc. of Arvada, Colo., also work well as materials for the shielding mirrors. Alternatively, the shielding mirrors may be made of glass or plastic having a suitable reflective coating, for example, 3M™ Solar Minor Film 1100, which is available from 3M Inc., St. Paul, Minn. In some implementations, the shielding mirrors are made from the same material as the reflectors, which can help to decrease manufacturing times and costs.

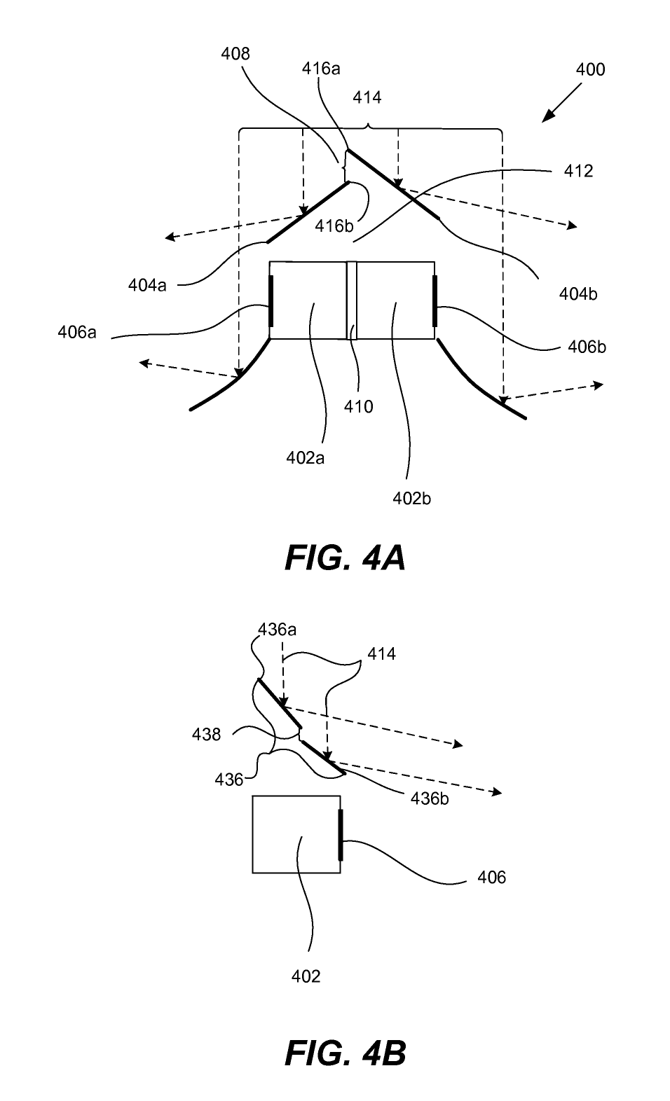

The size and shape of the shielding mirror can be modified to address different needs. For example, a reflective surface on the shielding mirror may be flat or curved. Some designs involve a shielding mirror that is segmented (e.g., includes multiple, individual mirrors that are separated from one another by one or more gaps, as illustrated in FIG. 4B.) Particular implementations involve larger shielding mirrors 208a-208d that are similar in size to the reflectors 204a-204d. In various other designs, the width, w, of a reflective surface on the shielding mirror is relatively small (e.g., less than approximately one, two or four times as large as the height of the solar cell, h, to which it is directing light.) A smaller width shielding mirror reduces the amount of concentration. In some circumstances, it is desirable to reduce the concentration factor. A high degree of concentration can require more precision in the orientation of the shielding mirror. In some embodiments the shielding mirror can have a slight convex curvature or bow along the longitudinal direction as described in U.S. patent application Ser. No. 12/846,620 filed on Jul. 29, 2010. The convex profile results in a spreading or fanning out of the reflected incoming sunlight expanding the size of the resultant flux line from a length of shielding mirror. The expansion of the flux line washes out the effect of any gaps between longitudinally adjacent shielding mirrors, increasing the flux line uniformity on the photovoltaic cells in the receiver.

In some implementations, the shape of the shielding mirror is substantially parabolic. A particular design involves a shielding mirror and associated reflector that each have a parabolic shape. The foci associated with each parabolic shape can be substantially coincident. For example, assume that a reflective surface on the first reflector 204a illustrated in FIG. 2 approximates a portion of a parabola and has a foci that helps to define the parabola. In various embodiments, a reflective surface of the first shielding mirror 208a, which is positioned above the first solar receiver 202a and a top edge of the first reflector 204a, may have a parabolic shape with a foci substantially coincident with the foci of first reflector 204a. The foci may be positioned behind the first solar receiver 202a. Such a shape is suitable for directing incident sunlight to one of the solar receivers. The shapes of the shielding mirrors and reflectors need not be parabolas, but may be shaped in any suitable manner to form an optimized uniform flux line as described in U.S. patent application Ser. No. 12/728,149 entitled “Reflective Surface for Solar Energy Collector” filed Mar. 19, 2010.

Preferably, there are one or more gaps 210 between each shielding mirror and its underlying solar receiver. The gap 210 creates room for air to flow above and/or through portions of the solar receiver. By way of example, some solar receiver designs involve a solar receiver with a heat sink (e.g., vertically oriented fins, etc.) The gap 210 facilitates natural convective air flow through and above the heat sink. One or more shielding mirror support structures, which extend upward from the solar receiver and support the shielding mirror, may help frame the gap 210.

Some implementations involve two shielding mirrors that are connected to cover two adjacent solar receivers whose photovoltaic cells face away from one another. An example of this design is shown in FIG. 2, which illustrates the centrally located second and third solar receivers 202b-202c, which are covered by the second and third shielding mirrors 208b-208c, respectively. The photovoltaic cells 206 of the second and third solar receivers 202b-202c face outward from one another. As indicated by arrows 212a and 212b, the second and third shielding mirrors 208b-208c reflect light in substantially (although not entirely) opposite directions. In some embodiments, the second and third shielding mirrors 208b-208c are integrally formed from a single piece of reflective material (e.g., a single piece of metal that is bent to form at least two reflective surfaces, etc.).

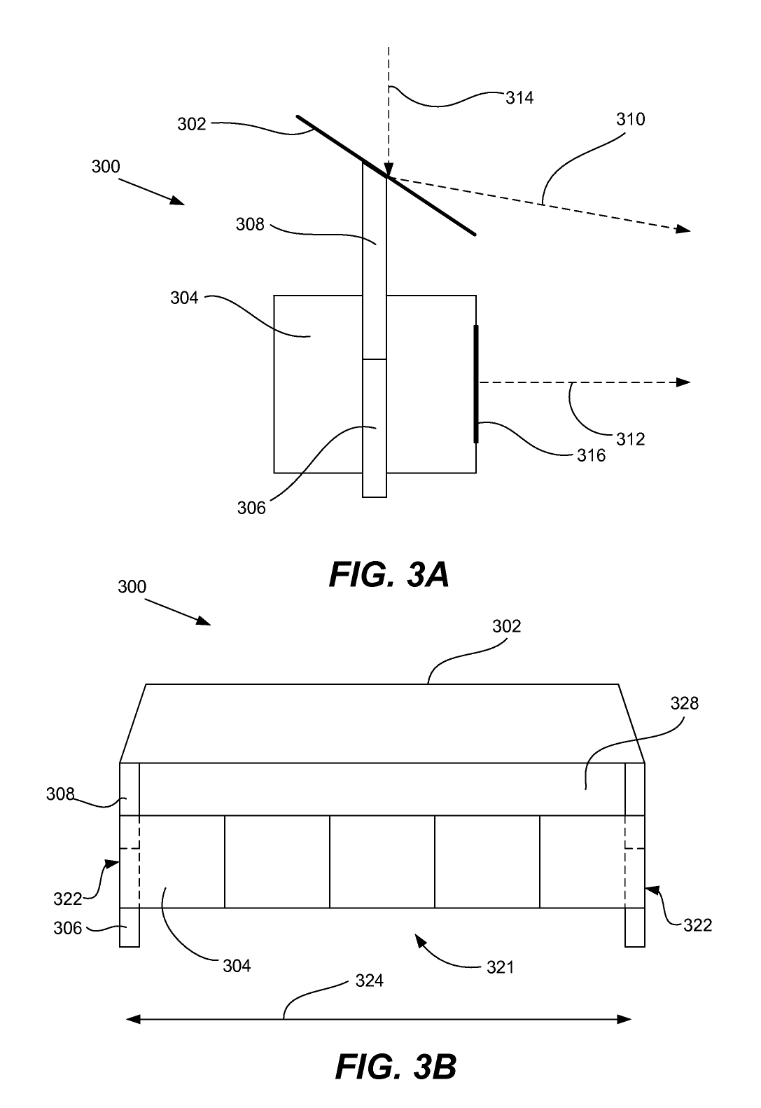

Referring now to FIGS. 3A and 3B, an arrangement 300 involving a solar receiver 304 and a shielding mirror 302 according to a particular embodiment of the present invention will be described. FIGS. 3A and 3B illustrate side and perspective frontal views of an arrangement 300 that includes a shielding mirror 302, one or more solar receivers 304, a receiver support structure 306 and a shielding mirror support structure 308. The arrangement 300 is suitable for use in a wide variety of photovoltaic concentrating systems, such as the solar collectors illustrated in FIGS. 2, 8 and 9.

The shielding mirror support structure 308 holds the shielding mirror 302 over the solar receiver 304 so that incident light 314 is reflected away from the solar receiver 304 and towards a suitable photovoltaic cell on another solar receiver. Generally, the shielding mirror 302 is arranged so that most or all of the incident light 314 that strikes the shielding mirror is directed away to one or more photovoltaic cells on a solar receiver that is different from the one that the shielding mirror 302 overlies. The light may be reflected in various directions depending on the alignment of the shielding mirror 302. In the illustrated embodiment, for example, the shielding mirror 302 is arranged to reflect light in a first direction 310 that is substantially similar to the second direction 312 in which the photovoltaic cell 316 on the underlying solar receiver 304 is facing. That is, the first and second directions 310/312 point substantially in the same horizontal direction, although their vertical alignment may differ somewhat.

The shielding mirror support structure 308 may be attached to various other parts of the solar collector. For example, the shielding mirror support structure 308 may be attached to a part of the underlying solar receiver. In some embodiments, the shielding mirror support structure 308 is mechanically coupled with a reflector. In still other embodiments, the shielding mirror support structure 308 is instead attached to the receiver support structure 306, which may be understood as any structure (e.g., a rail, a frame, a plate, etc.) that helps hold the one or more solar receivers 304 in place so that are they are properly aligned relative to other components of the solar collector. It is desirable for the shielding mirror support structure 308 and receiver support structure 306 to be positioned behind the photocell faces, so that they do not shadow the photocells.

FIG. 3B illustrates an example of this approach. In FIG. 3B, the solar receivers 304 are arranged side by side to form a solar receiver row 321 that extends in a longitudinal direction 324. The receiver support structures 306 are attached with the ends of the solar receiver row. The shielding mirror support structures 308 are attached in turn to the receiver support structures 306. The shielding mirror support structures 308, which take the form of beams in the illustrated embodiment, extend upwards from the ends of the solar receiver row 322 and are coupled with ends of the shielding mirror 302. The design illustrated in FIG. 3B allows a single, longitudinally extended shielding mirror 302 to cover and deflect light away from multiple solar receivers 304. The elevation of the shielding mirror 302 by its corresponding support structures also creates a gap 328 that allows convective air flow between the solar receivers 304 and the shielding mirror 302. This feature helps improve heat dissipation from the solar receivers 304. It should be appreciated that although FIG. 3A depicts the receiver support structure 306 and the shielding mirror support structure 308 as distinct elements, they may also be integrally formed as a single unit.

The receiver support structure 306 and the shielding mirror support structure 308 can take various forms. For example, although the shielding mirror support structure 308 in FIG. 3A takes the form of a beam that is attached with ends of the shielding mirror 304, it can have any other suitable shape (e.g., a hook, an arm, a latch, a frame, a stand, etc.) and support any surface of the shielding mirror 302 (e.g., the bottom surface, the top surface, the side surfaces, etc.). Various designs involve a shielding mirror support structure 308 that engages the receiver support structure 306 at discrete locations such that one or more gaps 324 are formed between the shielding mirror 302 and the underlying solar receiver(s) 304. In some implementations, the receiver support structure 306 takes the form of a plate that physically supports and extends below the photovoltaic cells of the solar receivers. In still other implementations, the receiver support structure 306 is a rail that the solar receivers 304 are mounted upon. Some designs involve a shielding mirror support structure 308 that is not directly attached to and/or is not in direct contact with the solar receiver 304, but is instead attached with the receiver support structure 306 or some other structural element of the collector. Various ways of physically supporting and aligning the solar receivers are described U.S. Pat. No. 7,820,906, entitled “Photovoltaic Receiver,” filed May 20, 2008, which is hereby incorporated by reference in its entirety for all purposes and is hereinafter referred to as the '906 patent.

It should be appreciated that FIGS. 3A and 3B are diagrammatic and that the solar receiver may include additional features or components not shown in the drawings. For example, each solar receiver may include one or more photovoltaic cells, heat fins and/or any of the features described in the '906 patent. In various embodiments, the solar receiver incorporates and/or is coupled with a fluid conduit and is arranged to heat fluid within the conduit when light is focused onto the solar receiver by the reflectors. The heated fluid may then be used for various purposes, such as supplying hot water.

Referring next to FIG. 4A, another arrangement 400 involving solar receivers and shielding mirrors according to a particular embodiment of the present invention will be described. The arrangement 400 includes a first solar receiver 402a and a second solar receiver 402b that are covered with a first shielding mirror 404a and a second shielding mirror 404b, respectively. The first and second shielding mirrors reflect and redirect incident sunlight 414, as discussed previously with respect to second and third shielding mirrors 202b/202c of FIG. 2. The face of a photovoltaic cell 406a on the first solar receiver 402a faces away from, entirely and/or substantially in the opposite direction of the face of the photovoltaic cell 406b on the second solar receiver 402b. There is a gap 408 between the first and second shielding mirrors 404a/404b. The arrangement illustrated in FIG. 4A may be used, for example, in place of the second and third solar receivers 202b/202c and shielding mirrors 208b/208c of FIG. 2.

The vertical gap 408, which is positioned between edges 416a/416b of the first and second shielding mirrors 404a/404b, is arranged to allow natural convective air flow. That is, the solar receivers 402a/402b heat the surrounding air, which can then pass through the gap 408 rather than being blocked by the shielding mirrors. The gap 408 thus helps dissipate heat from the solar receivers 402a/402b.

The first and second shielding mirrors 404a/404b may be physically supported over the solar receivers in various ways. By way of example, the first and second shielding mirrors 404a/404b may take the form of two distinct, non-continuous reflective surfaces. In some implementations, the first and second shielding mirrors 404a/404b are coupled together through a connecting portion that connects the edges 416/416b of the shielding mirrors and includes the gap 408. Some embodiments involve first and second shielding mirrors 404a/404b that lack the aforementioned gap and involve two, continuously connected reflective surfaces (e.g., the second and third shielding mirrors 208b/208c of FIG. 2).

The dissipation of heat may be facilitated by the existence of gaps in other or additional areas of the arrangement 400. In the illustrated embodiment, for example, there is a gap 410 between the first and second solar receivers 402a/402b. Additionally, there is a gap 412 between the shielding mirrors 404a/404b and the solar receivers 402a/402b. These gaps also are arranged to promote natural convective air flow to help cool the solar receivers 402a/402b.

Referring next to FIG. 4B, a shielding mirror/receiver arrangement according to another embodiment of the present invention will be described. In this embodiment the shielding mirror 436 is segmented, that is it is composed of a plurality of longitudinally extended, individual shielding mirrors 436a and 436b. The plurality of shielding mirrors 436a/436b may have a gap 438 between them to allow natural convective air flow. The air flow helps cool the solar receiver 402 and may lower the operating temperature of photovoltaic cell 406 improving its efficiency. The plurality of shielding mirrors 436a/436b may be flat or curved and may be oriented parallel to each other or in a non-parallel configuration as shown in FIG. 4B. The adjacent edges of the plurality of shielding mirrors may be arranged so that the lower edge of the top shielding mirror overlays the upper edge of the shielding mirror below it. This arrangement results in all incoming sunlight 414 that would strike the receiver being intercepted by one of the plurality of shielding mirrors 436a/436b.

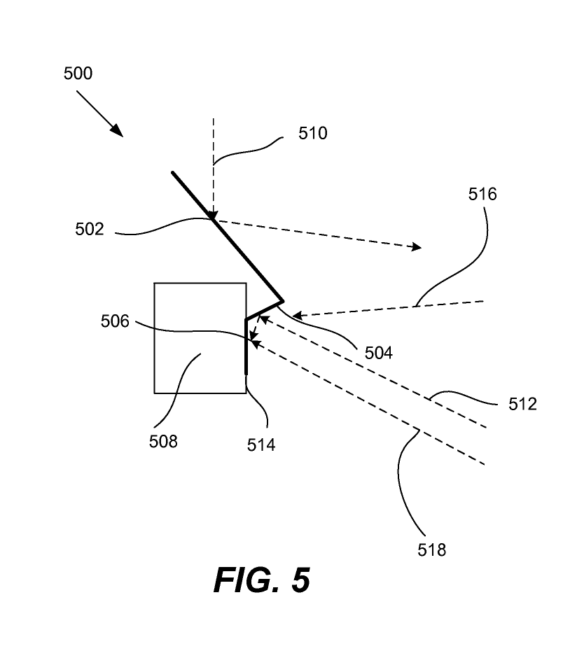

Referring next to FIG. 5, an arrangement 500 involving a solar receiver and a shielding mirror according to another embodiment of the present invention will be described. FIG. 5 illustrates an arrangement 500 with a solar receiver 508, a shielding mirror 502 and a secondary mirror 504. The arrangement 500 may be used in any suitable collector design (e.g., in place of any of the solar receivers in FIGS. 2, 8 and 9). As previously described with respect to other embodiments, the shielding mirror 502 is arranged to reflect incident light 510 away from the underlying solar receiver 508 and towards another solar receiver. In the illustrated embodiment, light is being reflected towards the solar receiver 508 from a reflector (as represented by rays 512 and 518) and from another shielding mirror (as represented by ray 516). The secondary mirror 504 is arranged to help capture light that would otherwise miss the cell 506 on the solar receiver 508 due to mechanical misalignment, a tracking error or some other reason. Therefore, this feature can help increase the acceptance angle for the solar collector.

The problem that the secondary mirror 504 addresses will be discussed with reference to FIGS. 2 and 5. Assume that the illustrated arrangement 500 took the place of the first solar receiver 202a in the solar collector 200 of FIG. 2. In the illustrated embodiment of FIG. 2, incident sunlight 209 is reflected by the second reflector 204b into the photovoltaic cell on the solar receiver 202a using a single reflection. However, this first reflection may not accurately direct all of the light into the photovoltaic cell, as shown by the light ray 512 in FIG. 5. The secondary mirror 504 is arranged to direct such light into the photovoltaic cell 506 using a second reflection.

The secondary mirror 504, photovoltaic cell 506, solar receiver 508 and shielding mirror 502 can be arranged in various ways. In the illustrated embodiment, for example, the secondary mirror 504 is positioned adjacent to and above the photovoltaic cell 506. Some designs involve a secondary mirror 504 that is attached to and extends out of the front surface 514 of the solar receiver 508. In other designs, the secondary mirror 504 is (also) attached to the shielding mirror 502. In FIG. 5, the shielding mirror 502 extends beyond a front edge of the solar receiver 514 to shade both the solar receiver 508 and the secondary mirror 504 from incident light. Thus, the extended shielding mirror 502 helps ensure that any incident sunlight that would otherwise be directly incident on the secondary mirror 504 is not wasted but is instead usefully directed to a photovoltaic cell. In some embodiments, the secondary mirror 504 and the shielding mirror 502 are integrally formed as a single structure (e.g., a bent metal structure with two reflective surfaces facing in different directions), while in other embodiments the mirrors are made of distinct elements that are fastened together and/or independently supported.

The secondary mirror 504 can be made of a wide variety of reflective materials. For example, the secondary mirror 504 can be made of the same materials as the shielding mirror 502 and/or the reflectors of the solar collector. Generally, any suitably reflective material, such as aluminum or Miro-Sun made by Alanod of Ennepatal, Germany, may be used to form the secondary mirror. Alternatively, the secondary mirror 504 may be made of glass or plastic having a suitable reflective coating. It may be desirable to have this reflective coating on the front surface of the secondary mirror 504 rather than the rear surface. By placing the reflective coating on the front surface the light rays 512 need not experience any absorptive losses associated with transmission through the secondary mirror substrate. The reflectivity of the secondary mirror 504 may thus be higher. In some embodiments, the secondary mirror 504 includes an optical component, such a prism or lens, which is suitable for concentrating light on a photovoltaic cell.

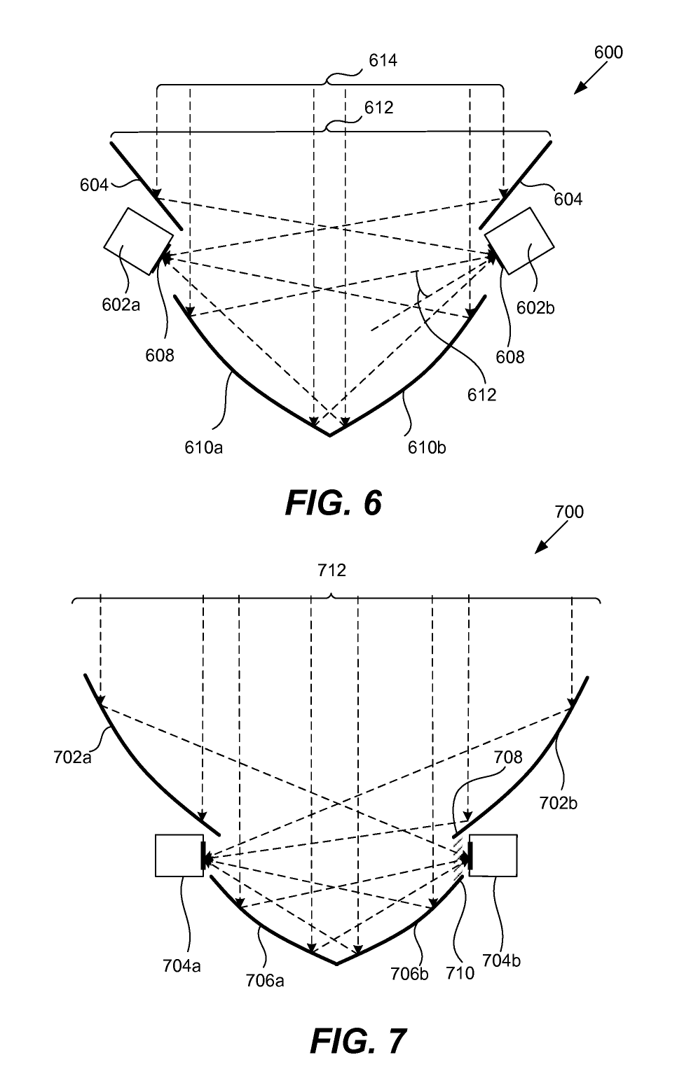

Referring next to FIG. 6, a solar collector 600 with tilted solar receivers 602a and 602b according to a particular embodiment of the present invention will be described. The shielding mirrors 604 overlie and shade the tilted solar receivers 602a/602b from incoming sunlight 614. In the illustrated embodiment, the solar receivers 602a/602b are tilted downwards. That is, the faces of the photovoltaic cells 608 on the solar receivers 602a/602b are not oriented perpendicular to the aperture 612 of the collector 600, but instead are angled more towards the reflectors 610b/610a. The tilting of the solar receivers can help reduce reflective losses from the receiver, thereby increasing the amount of sunlight that is absorbed by the photovoltaic cells 608.

By tilting the solar receiver 602a/602b more towards an associated reflector 610b/610a, the reflectors 610b/610a direct light at an angle that is more perpendicular to the face of the photovoltaic cell 608 on the solar receivers 602a/602b. That is, the angle of incidence 612 of solar radiation on the cell face of the solar receiver may be reduced. By way of example, the solar receiver 602b and the reflector 610a may be arranged such that the angle of incidence 612 of substantially all solar radiation that is reflected by the reflector 610b onto the cell 608 is less than approximately 40 degrees or less than 30 degrees or less than 20 degrees in a plane perpendicular to the optical aperture and longitudinal direction. A lower angle of incidence reduces the amount of sunlight that is reflected rather than absorbed by the surface of the photovoltaic cell, which in turn leads to more efficient power generation. Additionally, the tilting of the solar receiver may help form a narrower flux line on the face of the photovoltaic cell, which can allow for a decrease in the height of the photovoltaic cell.

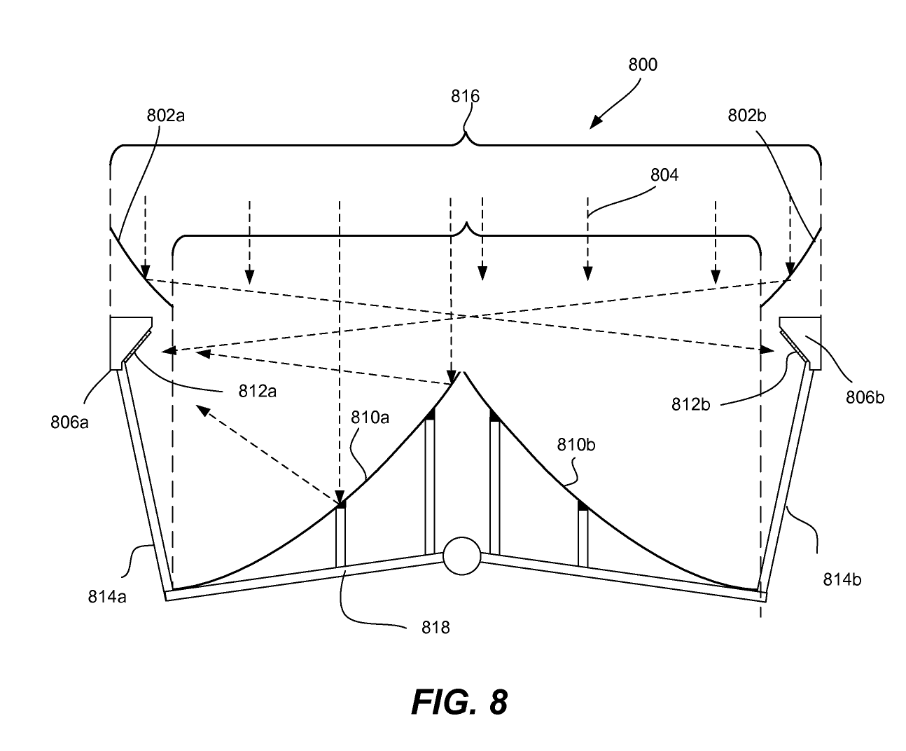

Referring next to FIG. 7, a solar collector 700 according to another embodiment of the present invention will be described. The solar collector 700, which shares some similarities with the solar collector designs of FIGS. 2 and 6, includes extended shielding mirrors 702a/702b. An extended shielding mirror can lead to efficiencies in electricity generation and manufacturing.

Various implementations of the present invention involve a shielding mirror 702a/702b that is similar in size to a reflector 706a/706b. In some embodiments, for example, the reflective areas of the reflector 706a and the shielding mirror 702a are within approximately 10% or 20% of one another. Similarly sized reflectors and shielding mirrors may be easier to fabricate using the same processing equipment, which can help reduce manufacturing costs.

Additionally, if the shielding mirrors, reflectors and solar receivers are sized and arranged in an appropriate manner, it is possible to reduce the angle of incidence of light on the photovoltaic cells. As discussed earlier, this can reduce the degree of reflection off of the cells and improve the efficiency of the solar collector. To understand how this may take place, it is helpful to compare FIG. 7 to FIG. 1. In the embodiment illustrated in FIG. 1, there are no shielding mirrors. The incident light in FIG. 1 strikes the second reflector 104b and is reflected to a cell on the first solar receiver 102a. It should be noted that this approach causes the light to be reflected mostly from a region below the cell, because the cell is generally higher than the second reflector 104b. In FIG. 7, however, assume that the combined width of the second reflector 706b and the second shielding mirror 702b is equal to the width of the second reflector 104b of FIG. 1. Thus, relatively speaking, the solar receiver is positioned more centrally relative to the same width of reflective surface. That is, light is reflected from the second shielding mirror 702b towards the first solar receiver 704a from a region that is positioned higher than the first solar receiver 704a. Light is also reflected from the second reflector 706b towards the first solar receiver 704a from a region that is positioned lower than the first solar receiver 704a. In comparison to the arrangement in FIG. 1, this arrangement can allow the angles of incidences of the reflected light on the cell face to be lower. Various implementations involve a shielding mirror 702b and a reflector 706b that are arranged to reflect light to a solar receiver 704a such that the range of angle of incidence of the reflected light on the face of the photovoltaic cell is less than 20 or 30 degrees.

Another noteworthy feature of the embodiment illustrated in FIG. 7 is the way in which edge portions 708 of the shielding mirrors 702a/702b extend beyond front edges of their underlying solar receivers 704a/704b. In the illustrated embodiment, for example, the second shielding mirror 702b extends far enough to overlie a portion of the underlying second reflector 706b, thus shading an edge portion 710 of the second reflector 706b from incident sunlight 712 during the normal operation of the collector. Since the incident light that would otherwise strike the shaded edge portion 710 of the second reflector 706b is usefully directed to a cell by the second shielding mirror 702b, this does not substantially reduce solar energy collection. The overlap is arranged to help prevent incident light from escaping through a region between the reflective surfaces of the second shielding mirror 702b and underlying second reflector 706b. Additionally, the overlap can also help shield any additional components that are connected with the solar receiver. Examples of such components are the secondary mirror described in connection with FIG. 5, and the wrap-around heat sink described in U.S. Provisional Patent Application No. 61/386,852, entitled “Solar Receiver with Wrap Around Heat Sink,” filed on Sep. 27, 2010, which is incorporated herein in its entirety for all purposes.

Referring next to FIG. 8, a solar collector 800 according to a particular embodiment of the present invention will be described. FIG. 8 illustrates another solar collector design that is described in U.S. Provisional Patent Application No. 61/362,591, entitled “Optimized Solar Collector,” filed on Jul. 8, 2010, which is hereby incorporated by reference in its entirety for all purposes and is hereinafter referred to as the '591 application. The solar collector 800 includes first and second reflectors 810a/810b, first and second solar receivers 806a/806b, and first and second shielding mirrors 802a/802b. The solar collector 800 is physically coupled with and supported by a support structure 818.

The solar collector 800 illustrated in FIG. 8 has various advantageous features. The reflectors 810a/810b are positioned relatively close to their associated solar receivers 806a/806b, which can improve tracking and mechanical tolerances and increase the acceptance angle for the collector. The solar receivers 806a/806b are supported at the periphery of the collector 800, which may improve heat dissipation and facilitate installation, maintenance and repair of the solar receivers. The faces of the photovoltaic cells 812a/812b are tilted downward, which can help reduce the angle of incidence of light on the cells, as discussed earlier with respect to FIG. 6.

In the illustrated embodiment of FIG. 8, the first and second reflectors 810a/810b are arranged substantially symmetrically around the center of the collector. A reflective surface on each reflector has a parabolic or otherwise curved shape. The first and second reflectors 810a/810b are arranged to form an “A”-like shape, i.e. the inner edges of the reflectors 810a/810b are positioned adjacent to one another at the middle of the collector, the reflectors 810a/810b curve inward relative to one another, and the outer edges of the reflectors 810a/810b are positioned at the periphery of the collector and at a lower height than the inner edges of the reflectors. The first and second solar receivers 806a/806b are positioned outside the outer edges of the first and second reflectors 810a/810b, respectively, and are physically supported by receiver support structures 814a/814b. Each shielding mirror 802a/802b is positioned over and shades a portion of or the entire underlying solar receiver 806a/806b from incident sunlight 804.

During the normal operation of the solar collector 800, the solar collector 800 tracks the movement of the sun such that incident light 804 is substantially perpendicular to the optical aperture 816 of the collector in the cross-sectional view of FIG. 8. The incoming solar radiation is reflected by a reflector or a shielding mirror and can follow various paths to a solar receiver. In the illustrated embodiment, for example, the first shielding mirror 802a, which is situated at one end of the collector 800, directs light to the second solar receiver 806b, which is situated underneath the second shielding mirror 802b at the opposite end of the collector. That is, the shielding mirrors 802a and 802b reflect light such that the light crosses most of the cross-sectional width of the collector 800. In the illustrated embodiment, light reflected by a reflector does not span the entire collector, but is generally limited to a region near where the reflector is positioned. For example, the first reflector 810a directs light towards the first solar receiver 806a, which is situated above a region outside the outer edge of the first reflector 810a. Similarly, the second reflector 810b directs light towards the second solar receiver 806b, which is situated above a region outside the outer edge of the second reflector 810b. In various implementations, the light reflected by a reflector and the light reflected by a shielding mirror overlap. By way of example, this could be the case with light reflected by the first reflector 810a and the light reflected by the second shielding mirror 802b.

It should be appreciated that various components of the solar collector may be modified as appropriate. For example, various implementations of the solar collector may include any feature described in the '591 application and the '730 patent. Additionally, the solar collector may incorporate any corresponding feature or component described in connection with the previously discussed figures.

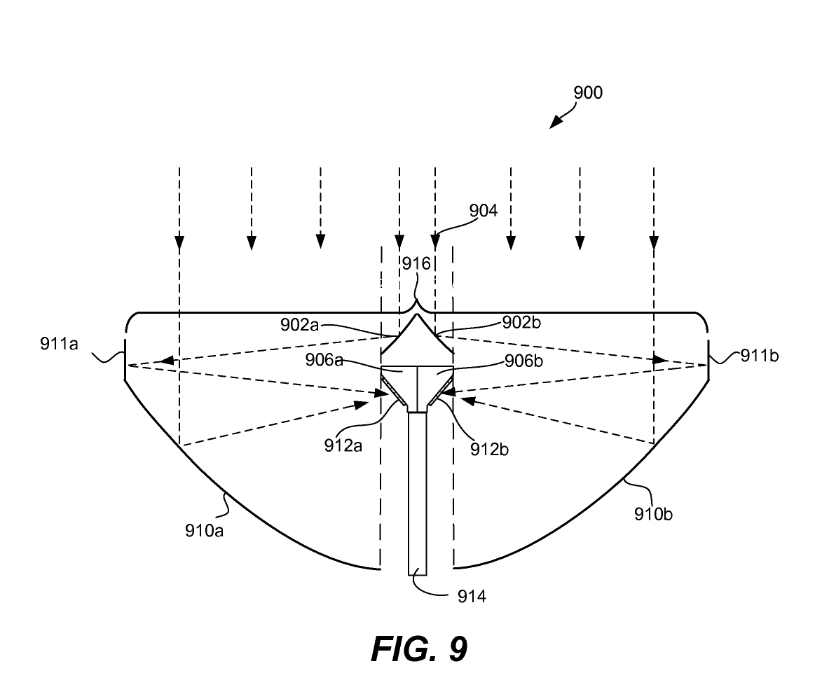

Referring next to FIG. 9, a solar collector in accordance with another embodiment of the present invention will be described. The solar collector 900 includes first and second reflectors 910a/910b that are arranged in a trough-like configuration. Reflector extenders 911a/911b are attached to the outer edges of the reflectors 910a/910b. Two solar receivers 906a/906b are positioned above a region between the inner edges of the reflectors and in the middle of the collector. Above the first and second solar receivers are the first and second shielding mirrors 902a/902b, respectively.

The solar collector design illustrated in FIG. 9 offers various advantages. Similar to the solar collector 800 illustrated in FIG. 8, the reflectors 910a/910b are in relatively close proximity with their associated solar receivers 906a/906b. As a result, the reflected light has less distance to travel to reach a suitable solar receiver. Additionally, some designs involve supporting the two solar receivers 906a/906b at the middle of the collector with a single receiver support structure 914, rather than a separate support structure for each solar receiver. Thus, substantially more electricity can be generated for the same amount of structural support. As discussed previously with respect to FIG. 2, the arrangement of the twin solar receivers 906a and 906b in the middle of the collector allows the overlying shielding mirrors 902a/902b to also be positioned close to one another at the middle of the collector. As a result, the first and second shielding mirrors 902a and 902b may be formed from a single, continuous reflective material with at least two reflective surfaces, although the shielding mirrors 902a/902b may be formed separately as well.

In the illustrated embodiment, the first and second reflectors 910a/910b, which may have a curved or parabolic shape, are substantially symmetrically arranged and curve outward to form a trough-like shape. That is, inner edges of the reflectors 910a/910b are positioned closer to the middle of the collector 900, while outer edges of the reflectors 910a/910b are positioned at the periphery of the collector 900. The outer edges are positioned higher than the inner edges forming a “U-like” shape. Twin solar receivers 906a/906b, whose respective photovoltaic cells 912a/912b face away from one another, are positioned over a region between the inner edges of the reflectors 910a/910b. The shielding mirrors 902a/902b are positioned over and shade the twin solar receivers from the incident sunlight 904.

In the illustrated embodiment, each solar receiver 906a/906b is tilted downward to face a respective reflector 910a/910b. The first reflector 910a is arranged to reflect incident light into the photovoltaic cell 912a on the first solar receiver 906a. The second reflector 910b is arranged to reflect incident light into the photovoltaic cell 912b on the second solar receiver 906b. The shielding mirrors 902a/902b are arranged to reflect light that would otherwise be directly incident on their underlying solar receivers 906a/906b. This light is reflected to reflector extenders 911a/911b that are positioned on the outer edges of the first and second reflectors 910a/910b. The first and second reflector extenders 911a/911b on the first and second reflectors 910a/910b reflect light to the first and second solar receivers 906a/906b, respectively. Thus, the reflectors 910a/910b direct light to the solar receivers 906a/906b using a single reflection, while the shielding mirrors 902a/902b and reflector extenders 911a/911b reflect light to the solar receivers 906a/906b using two reflections, although other implementations may involve different numbers of reflections. In this embodiment, the shielding mirrors help direct incident sunlight towards a photovoltaic cell on the solar receiver underlying the shielding mirror. Specifically shielding mirror 902a directs incoming sunlight 904 to photocell 912a on solar receiver 906a, which is beneath shielding mirror 902a. Similarly shielding mirror 902b directs incoming sunlight 904 to photocell 912b on solar receiver 906b, which is beneath shielding mirror 902b.

The reflector extender 911a/911b can be made of any suitable reflective material, and in some embodiments is made from the same material as the shielding mirror and/or the attached reflector. Some implementations involve a reflector extender that is formed integrally with its corresponding reflector from a single piece of reflective material, while in other implementations the reflector extender is a separate structure that is attached with the reflector. In the illustrated embodiment, the reflective surface of the reflector extender 911a/911b is flat and is oriented substantially perpendicular to the collector aperture 916, but the reflector extender 911a/911b may also be curved and/or angled, depending on the needs of a particular application.

The same concept of using a reflector extender may also be applied to the “A” style collector configuration depicted in FIG. 8. In this case the reflector extender(s) would be added to the upper edges of reflectors 810a/810b. The reflector extender(s) would intercept the rays reflected from the shielding mirrors 802a/802b and redirect them toward the associated receiver underlying the shielding mirror. That is, shielding mirror 802a would direct incoming sunlight to the reflector extender adjacent the edge of reflector 810a, which would in turn direct the sunlight to receiver 806a. Similarly shielding mirror 802b would direct incoming sunlight to the reflector extender adjacent the edge of reflector 810b, which would in turn direct the sunlight to receiver 806b. The reflector extender may be formed in a wide variety of ways. For example, the reflector extender may be integrally formed together with one of the reflectors 810a/810b. In other designs, it may be a distinct structure that is attached or fastened to the upper edges of the reflectors 810a/810b. In various embodiments, the reflector extender is formed from a metal plate with a reflective surface that extends in a longitudinal direction between the solar receivers 806a and 806b and/or that is arranged to be substantially perpendicular to the collector aperture 816.

Although only a few embodiments of the invention have been described in detail, it should be appreciated that the invention may be implemented in many other forms without departing from the spirit or scope of the invention. In the foregoing description, for example, sometimes multiple features are illustrated as being part of a single embodiment. These features, however, need not be combined in the same embodiment and one or more of the features may be placed in another, different embodiment. For example, FIG. 7 illustrates a shielding mirror 702a that 1) extends over a front edge of an underlying solar receiver 704a; 2) is similar in size to a reflector 706a; and 3) is arranged, together with the reflector 706a, to help reduce the angle of incidence of light on a photovoltaic cell. The present invention, however, also contemplates a shielding mirror that has any combination or subset of those features (e.g., the first feature but not the second and third features, etc.). It should be further appreciated that any feature (e.g., a shielding mirror that extends over the front edge of an underlying solar receiver) from one figure may be included in a corresponding component of another figure (e.g., any suitable shielding mirror of FIGS. 2, 8 and 9). Additionally, the present invention contemplates embodiments and features that are not specifically stated in the written specification but can be understood from the drawings. For example, FIG. 3A illustrates an arrangement 300 where the shielding mirror 302 directs light and/or faces in a first direction and the photovoltaic cell faces in a second direction. In some embodiments, for example, the first and second directions may have different vertical components but both have non-zero horizontal components with the same sign, where a vertical component is defined along an axis that is perpendicular to the collector aperture, and the horizontal component is defined along an axis that is parallel to the aperture and perpendicular to the longitudinal axis. In another embodiment, the shielding mirror and the photovoltaic cell in FIG. 3A face in substantially similar directions, in that they face at least partially in the same horizontal direction, although their vertical alignment may differ (e.g., the shielding mirror may face right but somewhat up, while the cell face also faces right but somewhat down, etc.). In the foregoing specification, there are some references to a width w of a reflector. It should be noted that this width may also refer to the total width of the reflective surface on the reflector, rather than a straightline width between ends or edges of the reflector. In other words, imagine two reflectors A and B, where both reflectors have opposing edges or ends that are the same distance apart. If reflector A is a flat plane that extends directly between the two ends of the reflector, and reflector B connects its two ends with a curved surface, then in this example the width of reflector B can be understood as being longer than the width of reflector A. It should be further appreciated that the width w in FIG. 2 is a dimension that runs perpendicular to a longitudinal axis that the reflectors extend along (i.e., the longitudinal axis extends into and out of the page of FIG. 2). Therefore, the present embodiments should be considered as illustrative and not restrictive and the invention is not limited to the details given herein, but may be modified within the scope and equivalents of the appended claims.

What is claimed is:

1. A concentrating solar collector suitable for use in a solar energy collection system that includes the collector, a support structure that supports the collector and a tracking system that causes the collector to track movements of the sun along at least one axis, the concentrating solar collector comprising:
a plurality of reflectors including a first reflector and a second reflector, each reflector extending along a longitudinal axis;
a plurality of solar receivers including a first solar receiver and a second solar receiver, each solar receiver extending along a longitudinal axis, each solar receiver including a photovoltaic cell, wherein the first and second reflectors are arranged to reflect incident sunlight to the first and second solar receivers, respectively; and
a plurality of shielding mirrors including a first shielding mirror and a second shielding mirror, each shielding mirror extending along a longitudinal axis, each shielding mirror being positioned over an associated solar receiver and arranged to reflect incident light away from the underlying associated solar receiver during the normal operation of the solar collector, wherein each shielding mirror is further arranged direct the reflected light to the photovoltaic cell on one of the solar receivers.

2. A concentrating solar collector as recited in claim 1, wherein:
the first and second reflectors each include an inner edge and an outer edge that extend in the longitudinal direction, the inner edges of the first and second reflectors being positioned closer to one another than the outer edges of the first and second reflectors, the first and second reflectors being arranged such that the inner edges of the first and second reflectors are positioned higher than the outer edges of the first and second reflectors;
the first and second solar receivers are positioned above peripheral regions that are outside the outer edges of the first and second reflectors;
the first shielding mirror, which is positioned over the first solar receiver, is arranged to direct incident light to the second solar receiver; and
the second shielding mirror, which is positioned over the second solar receiver, is arranged to direct incident light to the first solar receiver.

3. A concentrating solar collector as recited in claim 1, wherein:
the first and second reflectors each include an inner and an outer edge that extend in the longitudinal direction, the inner edges of the first and second reflectors being positioned closer to one another then the outer edges of the first and second reflectors, the first and second reflectors being arranged such that the outer edges of the first and second reflectors are positioned higher than the inner edges of the first and second reflectors;
the first and second solar receivers are positioned adjacent to one another over a region that is between the inner edges of the first and second reflectors, respectively;
the first shielding mirror that is positioned over the first solar receiver is arranged to help direct incident light to the first solar receiver; and
the second shielding mirror that is positioned over the second solar receiver is arranged to help direct incident light to the second solar receiver.

4. A concentrating solar collector as recited in claim 1, further comprising:
a reflector extender that is attached to each of the reflectors, each reflector extender arranged to direct light reflected by one of the shielding mirrors to one of the solar receivers, wherein each reflector extender includes a reflective surface that is oriented substantially perpendicular to an aperture of the solar collector.

5. A concentrating solar collector as recited in claim 1, wherein at least one of the plurality of shielding mirrors has a longitudinal bow to spread out reflected sunlight on at least one of the receivers.

6. A concentrating solar collector as recited in claim 1, wherein a width of each shielding mirror is less than approximately four times larger than the height of the photovoltaic cell to which the shielding mirror is arranged to direct light.

7. A concentrating solar collector as recited in claim 1, further comprising a plurality of secondary mirrors including a first secondary mirror and a second secondary mirror, the first and second secondary mirrors being positioned over and adjacent to the photovoltaic cell on the first and second solar receivers, respectively, the first and secondary mirrors aligned to direct light reflected by one selected from a group consisting of the first reflector, the second reflector, the first shielding mirror and the second shielding mirror.

8. A concentrating solar collector as recited in claim 1, wherein each shielding mirror is substantially flat.

9. A concentrating solar collector as recited in claim 1, wherein each shielding mirror is substantially curved.

10. A concentrating solar collector as recited in claim 1, wherein the cell face of the photovoltaic cell on each solar receiver is tilted towards an associated reflector such that the cell face is not oriented perpendicular to an aperture of the solar collector.

11. A concentrating solar collector as recited in claim 1, wherein the first and second solar receivers, the first and second reflectors and the first and second shielding mirrors are substantially symmetrically arranged.

12. A concentrating solar collector as recited in claim 1, wherein each solar receiver is thermally and physically coupled with a fluid conduit, each solar receiver being arranged to help heat a fluid passing through the fluid conduit.

13. A concentrating solar collector as recited in claim 1, wherein substantially all incoming sunlight that is substantially incident on the collector and that is directed towards the first and second solar receivers is reflected by the first and second shielding mirrors to the photovoltaic cells on the first and second solar receivers during the normal operation of the solar collector.

14. An arrangement that is suitable for use in a concentrating solar collector, the arrangement comprising:
a first solar receiver having a first photovoltaic cell; and
a first shielding mirror that is positioned over the first solar receiver to help deflect incident light away from the underlying first solar receiver, wherein the shielding mirror is arranged to direct the incident sunlight to a photovoltaic cell on another solar receiver that is different from the first solar receiver.

15. An arrangement as recited in claim 14, further comprising:
a second solar receiver that is positioned adjacent to the first solar receiver, the second solar receiver including a second photovoltaic cell, wherein the first and second photovoltaic cells of the first and second solar receivers face away from another; and
a second shielding mirror that is positioned over the second solar receiver to help deflect incident light away from the underlying second solar receiver.

16. An arrangement as recited in claim 15, wherein the first and second shielding mirrors are formed from a single piece of reflective material to form first and second reflective surfaces respectively, wherein the first and second reflective surfaces overlie and are arranged to deflect incident light away from the first and second solar receivers, respectively.

17. An arrangement as recited in claim 15, wherein there is a gap that creates room for natural convective air flow between the first and second adjacent solar receivers.

18. An arrangement as recited in claim 14, wherein the first shielding mirror includes a reflective surface that is substantially flat.

19. An arrangement as recited in claim 14, wherein the first shielding mirror includes a reflective surface that is substantially curved.

20. An arrangement as recited in claim 14, wherein the first shielding mirror overlies and extends beyond a front edge of the first solar receiver.

21. An arrangement as recited in claim 14, wherein there is a gap between the first shielding mirror and the underlying first solar receiver that allows natural convective air flow between the first shielding mirror and the first solar receiver.

22. An arrangement as recited in claim 14, further comprising:
a receiver support structure that physically supports the first solar receiver; and
a shielding mirror support structure that is coupled to the receiver support structure, the shielding mirror support structure extending above the first solar receiver to help support the first shielding mirror over the first solar receiver and to help form a gap between the first solar receiver and the first shielding mirror that allows natural convective air flow.

23. An arrangement as recited claim 22, wherein:
the arrangement includes a plurality of solar receivers that includes the first solar receiver, the plurality of solar receivers arranged side by side to form a solar receiver row;
the receiver support structure physically supports the solar receiver row; and
the shielding mirror support structure physically supports the first shielding mirror over the solar receiver row and engages the receiver support structure at discrete locations on the receiver support structure, thereby helping to form one or more gaps between the first shielding mirror and the underlying solar receiver row.

24. A concentrating solar collector suitable for use in a solar energy collection system, the solar collector comprising:
an arrangement as recited in claim 14;
a reflector; and
a secondary mirror positioned over and adjacent to the photovoltaic cell on the first solar receiver and aligned to direct light reflected by the reflector to the adjacent photovoltaic cell.

25. An arrangement as recited in claim 14, wherein:
the first shielding mirror is composed of a plurality of longitudinally extended individual mirrors; and
the plurality of longitudinally extended individual mirrors have gaps between them to allow for natural convective air flow.

26. An arrangement that is suitable for use in a concentrating solar collector, the arrangement comprising:
a solar receiver having a photovoltaic cell; and
a shielding mirror that is positioned over the solar receiver to help deflect incident light away from the underlying solar receiver, wherein the shielding mirror is arranged to direct the incident sunlight to a photovoltaic cell on the solar receiver.
